(19) United States
(12) Patent Application Publication
(10) Pub. No.: US 2025/0226222 A1
(43) Pub. Date: Jul. 10, 2025

(54) SUBSTRATE PROCESSING METHOD AND SUBSTRATE PROCESSING SYSTEM

(71) Applicant: Tokyo Electron Limited, Tokyo (JP)

(72) Inventors: Sho KUMAKURA, Miyagi (JP); Kenta ONO, Miyagi (JP); Yuta NAKANE, Miyagi (JP); Tetsuya NISHIZUKA, Miyagi (JP); Masanobu HONDA, Miyagi (JP)

(73) Assignee: Tokyo Electron Limited, Tokyo (JP)

(21) Appl. No.: 19/087,601

(22) Filed: Mar. 24, 2025

Related U.S. Application Data
(63) Continuation of application No. PCT/JP2023/034011, filed on Sep. 20, 2023.

(30) Foreign Application Priority Data
Sep. 27, 2022 (JP) 2022-153625

(51) Int. Cl. H01L 21/033; G03F 7/00; G03F 7/004; G03F 7/09; G03F 7/36; H01L 21/311

(52) U.S. Cl. CPC H01L 21/0332; G03F 7/0042; G03F 7/094; G03F 7/36; G03F 7/70033; H01L 21/31144

(57) ABSTRACT

A substrate processing method includes: a preparation operation of preparing a substrate having an underlying film; a first film-formation operation of forming a first film on the underlying film, the first film being made of a material containing an element having a higher EUV absorption cross section than the underlying film; and a second film-formation operation of forming a second film on the first film, the second film being a metal-containing resist film.

### CROSS-REFERENCE TO RELATED APPLICATIONS

This application is a bypass continuation application of International Application No. PCT/JP2023/034011 having an international filing date of Sep. 20, 2023 and designating the United States, the international application being based upon and claiming the benefit of priority from Japanese Patent Application No. 2022-153625, filed on Sep. 27, 2022, the entire contents of each are incorporated herein by reference.

### TECHNICAL FIELD

Exemplary embodiments of the present disclosure relate to a substrate processing method and a substrate processing system.

### BACKGROUND

Patent Document 1 discloses a technique for forming a thin film which may be patterned on a semiconductor substrate using extreme ultraviolet light (hereinafter, referred to as “EUV light”).

### PRIOR ART DOCUMENT

### Patent Document

Patent Document 1: International Application Japanese Translation Publication No. 2021-523403

### SUMMARY

According to an exemplary embodiment of the present disclosure, a substrate processing method includes a preparation operation of preparing a substrate having an underlying film; a first film-formation operation of forming a first film on the underlying film, the first film being made of a material containing an element having a higher EUV absorption cross section than the underlying film; and a second film-formation operation of forming a second film on the first film, the second film being a metal-containing resist film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining an exemplary configuration of a heat treatment system.

FIG. 2 is a diagram for explaining an exemplary configuration of a plasma treatment system.

FIG. 3 is a diagram for explaining an exemplary configuration of a capacitively-coupled plasma treatment apparatus.

FIG. 4 is a diagram for explaining an exemplary configuration of a liquid treatment system.

FIG. 5 is a flowchart showing a processing method of the present disclosure.

FIG. 6 is a diagram showing an example of an underlying film of a substrate.

FIG. 7 is a diagram showing an example of the underlying film of the substrate.

FIG. 8 is a diagram showing an example of a cross-sectional structure of the substrate on which a first film is formed.

FIG. 9 is a flowchart showing an example of Step using an ALD method.

FIG. 10 is a diagram showing an example of a phenomenon occurring on a surface of the substrate in Step using the ALD method.

FIG. 11 is a diagram showing an example of a cross-sectional structure of the substrate on which a second film is formed.

FIG. 12 is a diagram showing an example of a cross-sectional structure of the substrate exposed to EUV.

FIG. 13 is a diagram showing another example of the cross-sectional structure of the substrate exposed to EUV.

FIG. 14 is a diagram showing an example of a cross-sectional structure of the substrate after development.

FIG. 15 is a diagram showing another example of the cross-sectional structure of the substrate after development.

FIG. 16 is a block diagram for explaining an exemplary configuration of a substrate processing system.

FIG. 17 is a flowchart showing a method.

### DETAILED DESCRIPTION

Various embodiments of the present disclosure will be described below. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

According to an exemplary embodiment of the present disclosure, there is provided a substrate processing method including: a preparation operation of preparing a substrate having an underlying film; a first film-formation operation of forming a first film on the underlying film, the first film being made of a material containing an element having a higher EUV absorption cross section than the underlying film; and a second film-formation operation of forming a second film on the first film, the second film being a metal-containing resist film.

In an exemplary embodiment, the first film contains at least one metal selected from a group consisting of Sn, At, Bi, Ti, Pb, Xe, I, Te, Sb, Hg, Au, Cd, In, Ge, and Ag.

In an exemplary embodiment, the first film contains Sn.

In an exemplary embodiment, a composition ratio of the metal in the first film is higher than a composition ratio of a metal in the second film.

In an exemplary embodiment, the first film is a metal-containing resist film.

In an exemplary embodiment, in the first film-formation operation, the first film is formed using a dry process.

In an exemplary embodiment, in the first film-formation operation, the first film is formed using a wet process.

In an exemplary embodiment, the second film contains at least one metal selected from a group consisting of Sn, Hf, and Ti.

In an exemplary embodiment, the second film contains Sn.

In an exemplary embodiment, the second film is thicker than the first film.

In an exemplary embodiment, in the second film-formation operation, the second film is formed using a dry process.

In an exemplary embodiment, in the second film-formation operation, the second film is formed using a wet process.

In an exemplary embodiment, the substrate processing method further includes an exposure operation of exposing the substrate to form an exposed first region and an unexposed second region in the second film after the second film-formation operation.

In an exemplary embodiment, the substrate processing method further includes a developing operation of developing the substrate to selectively remove the unexposed second region from the second film after the exposure operation.

In an exemplary embodiment, the substrate processing method further includes a first etching operation of etching the first film using the second film as a mask after the developing operation.

In an exemplary embodiment, the substrate processing method further includes a second etching operation of etching the underlying film using the first film and the second film as the mask after the first etching operation.

In an exemplary embodiment, the substrate processing method further includes an exposure operation of exposing the substrate to form an exposed first region and an unexposed second region in the first film and the second film after the second film-formation operation.

In an exemplary embodiment, the substrate processing method further includes a developing operation of developing the substrate to selectively remove the unexposed second region from the first film and the second film after the exposure operation.

In an exemplary embodiment, the substrate processing method further includes an etching operation of etching the underlying film using the first film and the second film as a mask after the developing operation.

According to an exemplary embodiment, there is provided a substrate processing method including: preparing a substrate including an underlying film, a first film on the underlying film, and a second film on the first film, wherein the first film has a higher secondary electron emission coefficient than the underlying film, the second film is a metal-containing resist film, and each of the first film and the second film has an exposed first region and an unexposed second region; and developing the substrate to selectively remove the unexposed second region from the first film and the second film.

According to an exemplary embodiment, there is provided a substrate processing system including: one or more substrate processing apparatuses; and a controller configured to control the one or more substrate processing apparatuses to execute: preparing a substrate including an underlying film; forming a first film on the underlying film, the first film being made of a material containing an element having a higher EUV absorption cross section than the underlying film; and forming a second film on the first film, the second film being a metal-containing resist film.

Hereinafter, various embodiments of the present disclosure will be described in detail with reference to the drawings. The same or similar elements in the drawings will be denoted by the same reference numerals, and descriptions thereof will be omitted. Unless otherwise specified, positional relationships such as upward, downward, leftward, rightward, and the like will be described based on positional relationships shown in the drawings. Dimension ratios in the drawings do not coincide with actual dimension ratios, and the actual dimension ratios are not limited to the dimension ratios shown in the drawings.

### <Exemplary Configuration of Heat Treatment System>

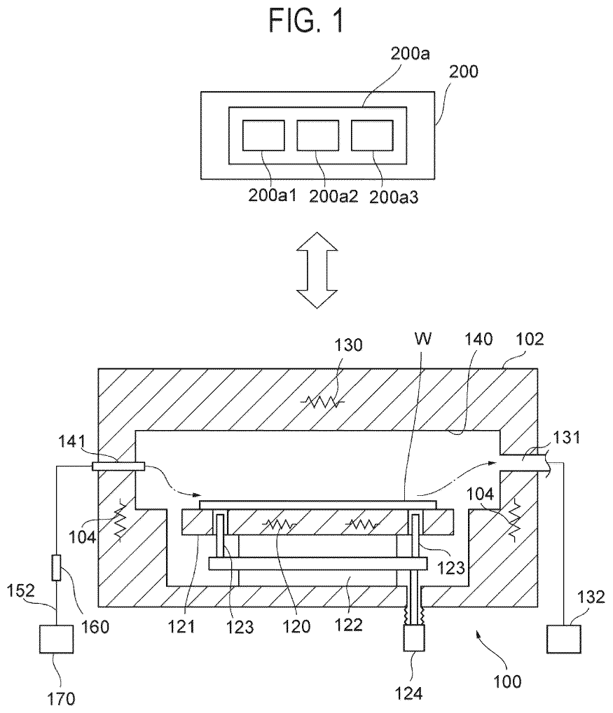

FIG. 1 is a diagram for explaining an exemplary configuration of a heat treatment system. In one embodiment, the heat treatment system includes a heat treatment apparatus 100 and a controller 200. The heat treatment system is an example of a substrate processing system, and the heat treatment apparatus 100 is an example of a substrate processing apparatus.

The heat treatment apparatus 100 includes a processing chamber 102 configured to be capable of forming a sealed space. The processing chamber 102 is, for example, an airtight cylindrical container, and is configured to be capable of adjusting an internal atmosphere. A sidewall heater 104 is provided on a sidewall of the processing chamber 102. A ceiling heater 130 is provided on a ceiling wall (ceiling plate) of the processing chamber 102. A ceiling surface 140 of the ceiling wall (ceiling plate) of the processing chamber 102 is formed as a horizontal flat surface. A temperature of the ceiling surface 140 is adjusted by the ceiling heater 130.

A substrate support 121 is provided in a lower portion of the interior of the processing chamber 102. The substrate support 121 has a substrate support surface on which a substrate W is supported. The substrate support 121 is formed in, for example, a circular shape in a plan view. The substrate W is placed on a horizontal surface (upper surface) of the substrate support 121. A stage heater 120 is buried in the substrate support 121. The stage heater 120 may heat the substrate W placed on the substrate support 121. In addition, a ring assembly (not shown) may be disposed on the substrate support 121 so as to surround the substrate W. The ring assembly may include one or more annular members. By disposing the ring assembly around the substrate W, a temperature controllability of an outer peripheral region of the substrate W may be improved. The ring assembly may be made of an inorganic material or an organic material according to an intended heat treatment.

The substrate support 121 is supported in the interior of the processing chamber 102 by a pillar 122 provided on a bottom surface of the processing chamber 102. A plurality of lift pins 123 which may be vertically raised/lowered are provided outside the pillar 122 in a circumferential direction. The plurality of lift pins 123 are inserted into respective through-holes formed in the substrate support 121. The plurality of lift pins 123 are arranged at intervals in the circumferential direction. An up-down movement of the plurality of lift pins 123 is controlled by a lift mechanism 124. When the lift pins 123 protrude from the surface of the substrate support 121, the substrate W may be transferred between a transfer mechanism (not shown) and the substrate support 121.

An exhaust port 131 having an opening is provided in the sidewall of the processing chamber 102. The exhaust port 131 is connected to an exhaust mechanism 132 via an exhaust pipe. The exhaust mechanism 132 is constituted with a vacuum pump, a valve, and the like, and adjusts an exhaust flow rate of a gas exhausted from the exhaust port 131. An internal pressure of the processing chamber 102 is adjusted by adjusting the exhaust flow rate, or the like by the exhaust mechanism 132. In addition, a transfer port (not shown) for the substrate W is formed to be capable of being opened and closed in the sidewall of the processing chamber 102 at a position different from a position where the exhaust port 131 is open.

In addition, a gas nozzle 141 is provided in the sidewall of the processing chamber 102 at a position different from the positions of the exhaust port 131 and the transfer port for the substrate W. The gas nozzle 141 supplies a processing gas to the interior of the processing chamber 102. The gas nozzle 141 is provided in the sidewall of the processing chamber 102 on a side facing the exhaust port 131 as viewed from the center of the substrate support 121. That is, the gas nozzle 141 is provided in the sidewall of the processing chamber 102 symmetrically with the exhaust port 131 with respect to a vertical virtual plane passing through the center of the substrate support 121.

The gas nozzle 141 is formed in a rod shape protruding from the sidewall of the processing chamber 102 toward the center of the processing chamber 102. For example, a leading end of the gas nozzle 141 extends horizontally from the sidewall of the processing chamber 102. The processing gas is discharged into the processing chamber 102 from a discharge port which is open at the leading end of the gas nozzle 141, flows in a direction indicated by the one-dot chain line arrow in FIG. 1, and is exhausted via the exhaust port 131. The leading end of the gas nozzle 41 may have a shape extending obliquely downward toward the substrate W, or may have a shape extending obliquely upward toward the ceiling surface 140 of the processing chamber 102.

The gas nozzle 141 may be provided in, for example, the ceiling wall of the processing chamber 102. In addition, the exhaust port 131 may be provided in the bottom surface of the processing chamber 102.

The heat treatment apparatus 100 includes a gas supply pipe 152 connected to the gas nozzle 141 from the outside of the processing chamber 102. A pipe heater 160 for heating a gas in the gas supply pipe 152 is provided around the gas supply pipe 152. The gas supply pipe 152 is connected to the gas supply 170. The gas supply 170 includes at least one gas source and at least one flow rate controller. The gas supply 170 may include a vaporizer configured to vaporize a material in a liquid state.

The controller 200 processes computer-executable instructions that cause the heat treatment apparatus 100 to execute various operations which will be described in the present disclosure. The controller 200 may be configured to control individual constituent elements of the heat treatment apparatus 100 to execute various operations to be described herein. In one embodiment, a part or all of the controller 200 may be included in the heat treatment apparatus 100. The controller 200 may include a processor 200a1, a storage 200a2, and a communication interface 200a3. The controller 200 is implemented by, for example, a computer 200a. The processor 200al may be configured to read a program from the storage 200a2 and execute the read program to execute various control operations. The program may be stored in the storage 200a2 in advance, or may be acquired from a medium when necessary. The acquired program is stored in the storage 200a2 and is read and executed from the storage 200a2 by the processor 200a1. The medium may be various non-transitory computer-readable storage media readable by the computer 200a, or may be a communication line connected to the communication interface 200a3. The processor 200al may be a CPU (Central Processing Unit). The storage 200a2 may include a RAM (Random Access Memory), a ROM (Read Only Memory), an HDD (Hard Disk Drive), an SSD (Solid State Drive), or a combination thereof. The communication interface 200a3 may communicate with the heat treatment apparatus 100 via a communication line such as a LAN (Local Area Network).

### <Exemplary Configuration of Plasma Treatment System>

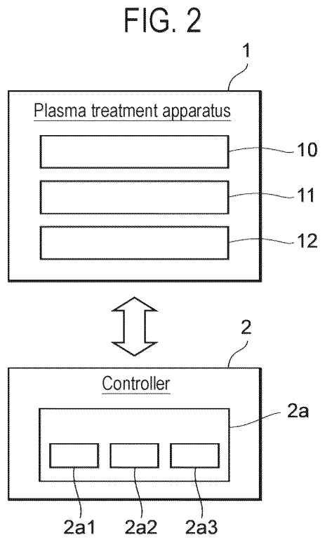

FIG. 2 is a diagram for explaining an exemplary configuration of a plasma treatment system. In one embodiment, the plasma treatment system includes a plasma treatment apparatus 1 and a controller 2. The plasma treatment system is an example of the substrate processing system, and the plasma treatment apparatus 1 is an example of the substrate processing apparatus. The plasma treatment apparatus 1 includes a plasma processing chamber (hereinafter, also simply referred to as a “processing chamber”) 10, a substrate support 11, and a plasma generator 12. The plasma processing chamber 10 has a plasma processing space. Further, the plasma processing chamber 10 includes at least one gas supply port for supplying at least one processing gas into the plasma processing space, and at least one gas discharge hole for discharging a gas from the plasma processing space. The gas supply port is connected to a gas supply 20 to be described later. The gas discharge hole is connected to an exhaust system 40 to be described later. The substrate support 11 is disposed in the plasma processing space and has a substrate support surface for supporting the substrate thereon.

The plasma generator 12 is configured to generate plasma from the at least one processing gas supplied into the plasma processing space. The plasma formed in the plasma processing space may be capacitively coupled plasma (CCP), an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In one embodiment, an AC signal (AC power) used in the AC plasma generator has a frequency in a range of 100 kHz to 10 GHz. Thus, the AC signal includes a radio frequency (RF) signal and a microwave signal. In one embodiment, the RF signal has a frequency in a range of 100 kHz to 150 MHz.

The controller 2 processes computer-executable instructions that cause the plasma treatment apparatus 1 to execute various operations to be described in the present disclosure. The controller 2 may be configured to control individual constituent elements of the plasma treatment apparatus 1 to execute the various operations described herein. In one embodiment, a part or all of the controller 2 may be included in the plasma treatment apparatus 1. The controller 2 is implemented by, for example, a computer 2a. The controller 2 may include a processor 2a1, a storage 2a2, and a communication interface 2a3. Each configuration of the controller 2 may be the same as each configuration of the above-described controller 200 (see FIG. 1).

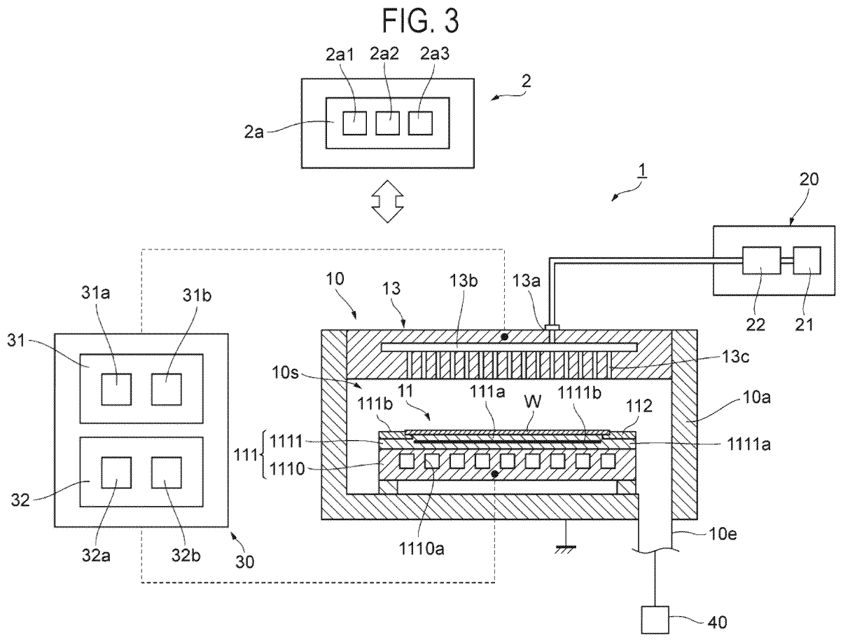

Hereinafter, an exemplary configuration of the capacitively coupled plasma treatment apparatus as an example of the plasma treatment apparatus 1 will be described. FIG. 3 is a diagram for explaining the exemplary configuration of the capacitively coupled plasma treatment apparatus.

The capacitively coupled plasma treatment apparatus 1 includes a plasma processing chamber 10, a gas supply 20, a power supply 30, and an exhaust system 40. Further, the plasma treatment apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of the ceiling of the plasma processing chamber 10. The plasma processing chamber 10 has a plasma processing space 10s defined by the shower head 13, the sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting the substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also referred to as a substrate support surface for supporting the substrate W thereon, and the annular region 111b is also referred to as a ring support surface for supporting the ring assembly 112 thereon.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF power supply 31 and/or a DC power supply 32, which will be described later, may be disposed in the ceramic member 1111a. In this case, the at least one RF/DC electrode functions as a lower electrode. In a case in which a bias RF signal and/or a DC signal to be described later is supplied to the at least one RF/DC electrode, the RF/DC electrode may be referred to as a bias electrode. The conductive member of the base 1110 and the at least one RF/DC electrode may function as a plurality of lower electrodes. In addition, the electrostatic electrode 1111b may function as a lower electrode. Thus, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

Further, the substrate support 11 may include a temperature adjustment module configured to adjust a temperature of at least one of the electrostatic chuck 1111, the ring assembly 112, or the substrate to a target temperature. The temperature adjustment module may include a heater, a heat-transfer medium, a flow passage 1110a, or a combination thereof. A heat transfer fluid such as brine or a gas flows through the flow passage 1110a. In one embodiment, the flow passage 1110a is formed in the base 1110, and one or more heaters are disposed in the ceramic member 1111a of the electrostatic chuck 1111. Further, the substrate support 11 may include a heat-transfer gas supply configured to supply a heat-transfer gas to a gap between the back surface of the substrate W and the central region 111a.

The shower head 13 is configured to introduce at least one processing gas from the gas supply 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s via the plurality of gas introduction ports 13c. Further, the shower head 13 includes at least one upper electrode. In addition to the shower head 13, the gas introduction unit may include one or more side gas injectors (SGIs) attached to one or more opening portions formed in the sidewall 10a.

The gas supply 20 may include at least one gas source 21 and at least one flow rate controller 22. In one embodiment, the gas supply 20 is configured to supply at least one processing gas from a corresponding gas source 21 to the shower head 13 via a corresponding flow rate controller 22. Each flow rate controller 22 may include, for example, a mass flow controller or a pressure-controlled flow rate controller. Further, the gas supply 20 may include at least one flow modulation device configured to modulate or pulse a flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Thus, the RF power supply 31 may function as at least a portion of the plasma generator 12. In addition, the RF power supply 31 may supply a bias RF signal to at least one lower electrode to generate a bias potential on the substrate W. Ion components in the plasma thus formed may be drawn into the substrate W.

In one embodiment, the RF power supply 31 includes a first RF generator 31a and a second RF generator 31b. The first RF generator 31a is configured to be coupled to at least one lower electrode and/or at least one upper electrode via at least one impedance matching circuit so as to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. One or more source RF signals thus generated are supplied to at least one lower electrode and/or at least one upper electrode.

The second RF generator 31b is configured to be coupled to at least one lower electrode via at least one impedance matching circuit so as to generate the bias RF signal (bias RF power). A frequency of the bias RF signal may be the same as or different from that of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. One or more bias RF signals thus generated are supplied to at least one lower electrode. In various embodiments, at least one of the source RF signal or the bias RF signal may be pulsed.

Further, the power supply 30 may include a DC power supply 32 coupled to the plasma processing chamber 10. The DC power supply 32 includes a first DC generator 32a and a second DC generator 32b. In one embodiment, the first DC generator 32a is configured to be connected to at least one lower electrode so as to generate a first DC signal. The first DC signal thus generated is applied to the at least one lower electrode. In one embodiment, the second DC generator 32b is configured to be connected to at least one upper electrode so as to generate a second DC signal. The second DC signal thus generated is applied to the at least one upper electrode.

In various embodiments, the first and second DC signals may be pulsed. In this case, a sequence of voltage pulses is applied to at least one lower electrode and/or at least one upper electrode. The voltage pulses may have a pulse waveform that is rectangular, trapezoidal, triangular, or a combination thereof. In one embodiment, a waveform generator for generating the sequence of voltage pulses from the DC signal is connected between the first DC generator 32a and at least one lower electrode. Thus, the first DC generator 32a and the waveform generator constitute a voltage pulse generator. When the second DC generator 32b and the waveform generator constitute the voltage pulse generator, the voltage pulse generator is connected to at least one upper electrode. The voltage pulse may have a positive polarity or a negative polarity. In addition, the sequence of voltage pulses may include one or more positive voltage pulses and one or more negative voltage pulses in one period. The first DC generator 32a and the second DC generator 32b may be provided in addition to the RF power supply 31, or the first DC generator 32a may be provided instead of the second RF generator 31b.

The exhaust system 40 may be connected to, for example, a gas discharge hole 10e provided in the bottom of the plasma processing chamber 10. The exhaust system 40 may include a pressure regulating valve and a vacuum pump. An internal pressure of the plasma processing space 10s is adjusted by the pressure regulating valve. The vacuum pump may include a turbo-molecular pump, a dry pump, or a combination of these pumps.

### <Exemplary Configuration of Liquid Treatment System>

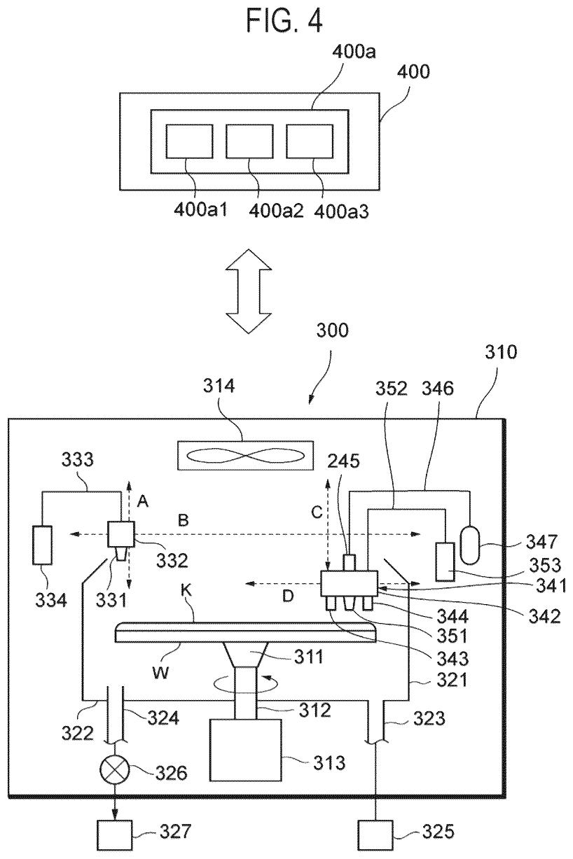

FIG. 4 is a diagram for explaining an exemplary configuration of a liquid treatment system. In one embodiment, the liquid treatment system includes a liquid treatment apparatus 300 and a controller 400. The liquid treatment system is an example of the substrate processing system, and the liquid treatment apparatus 300 is an example of the substrate processing apparatus.

As shown in FIG. 4, the liquid treatment apparatus 300 includes a spin chuck 311 as a substrate support provided in a processing chamber 310. The spin chuck 311 holds the substrate W horizontally. The spin chuck 311 is connected to a vertically-movable rotator 312. The rotator 312 is connected to a rotation drive 313 including a motor and the like. The substrate W held by the spin chuck 311 may be rotated with the driving of the rotation drive 313.

A cup 321 is disposed outside the spin chuck 311 to prevent a processing liquid (resist liquid, developing solution, cleaning liquid, or the like) or mist of the processing liquid from scattering around the cup 321. A drainage pipe 323 and an exhaust pipe 324 are provided in a bottom 322 of the cup 321. The drainage pipe 323 is connected to a drainage device 325 such as a drainage pump. The exhaust pipe 324 is connected to an exhaust device 327 such as an exhaust pump via a valve 326.

A blower 314 is provided at an upper portion of the processing chamber 310 of the liquid treatment apparatus 300 to supply air having a required temperature and humidity inward of the cup 321 in a down-flow manner.

A processing-liquid supply nozzle 331 is used to form a paddle of the processing liquid on the substrate W. The processing-liquid supply nozzle 331 is provided in a nozzle support 332 such as an arm. By a drive mechanism, the nozzle support 332 may be movable vertically in a direction of a reciprocating arrow A indicated by a broken line in FIG. 4, and may be movable horizontally in a direction of a reciprocating arrow B indicated by a broken line in FIG. 4. The processing liquid (resist liquid, developing solution, or the like) is supplied to the processing-liquid supply nozzle 331 from a processing-liquid source 334 via a supply pipe 333.

In a case in which a so-called long nozzle with a discharge port having a length equal to or longer than that of the substrate W is used, the paddle of the processing liquid may be formed on the substrate W by scanning the substrate W from its one end to its other end. In a case in which a so-called straight type nozzle that discharges a liquid to form a liquid column with a width sufficiently smaller than the diameter of the substrate W is used, the paddle of the processing liquid may be formed on the substrate W by arranging the discharge port above the center of the substrate W and discharging the processing liquid to spread the processing liquid over the entire surface of the substrate W while rotating the substrate W. In addition, the paddle of the processing liquid may be formed by scanning the straight type nozzle over the substrate W in the same manner as that used in the long nozzle, or by arranging discharge ports for discharging a liquid over a plurality of substrates W in the same manner as that used in the straight type nozzle and supplying the processing liquid from each discharge port.

A gas nozzle 341 includes a nozzle body 342. The nozzle body 342 is provided on a nozzle support such as an arm. By the drive mechanism, the nozzle support may be movable vertically by a drive mechanism in a direction of a reciprocating arrow C indicated by a broken line in FIG. 4, and may be movable horizontally in a direction of a reciprocating arrow D indicated by a broken line in FIG. 4.

The gas nozzle 341 includes two nozzle discharge ports 343 and 344. The nozzle discharge ports 343 and 344 are formed to be branched at a gas flow path 345. The gas flow path 345 is connected to a gas source 347 via a gas supply pipe 346. The gas source 347 stores an inert gas or a non-oxidizing gas, such as a nitrogen gas. For example, when the nitrogen gas is supplied to the gas nozzle 341 from the gas flow path 345, the nitrogen gas is discharged from each of the nozzle discharge ports 343 and 344.

Further, the gas nozzle 341 is provided with a cleaning-liquid supply nozzle 351 for washing off the processing liquid, which has been subjected to the liquid processing, from the substrate W. The cleaning-liquid supply nozzle 351 is connected to a cleaning-liquid source 353 via a cleaning-liquid supply pipe 352. For example, pure water is used as the cleaning liquid. The cleaning-liquid supply nozzle 351 is located between the above-mentioned two nozzle discharge ports 343 and 344, but the location is not limited thereto. The cleaning-liquid supply nozzle 351 may be provided independently of the gas nozzle 341.

The controller 400 processes computer-executable instructions that cause the liquid treatment apparatus 300 to execute various operations described in the present disclosure. The controller 400 may be configured to control individual constituent elements of the liquid treatment apparatus 300 to execute the various operations described herein. In one embodiment, a part or all of the controller 400 may be included in the liquid treatment apparatus 300. The controller 400 is implemented by, for example, a computer 400a. The computer 400a may include a processor 400a1, a storage 400a2, and a communication interface 400a3. Individual configurations of the controller 400 may be the same as those of the above-described controller 200 (see FIG. 1).

### <Example of Substrate Processing Method>

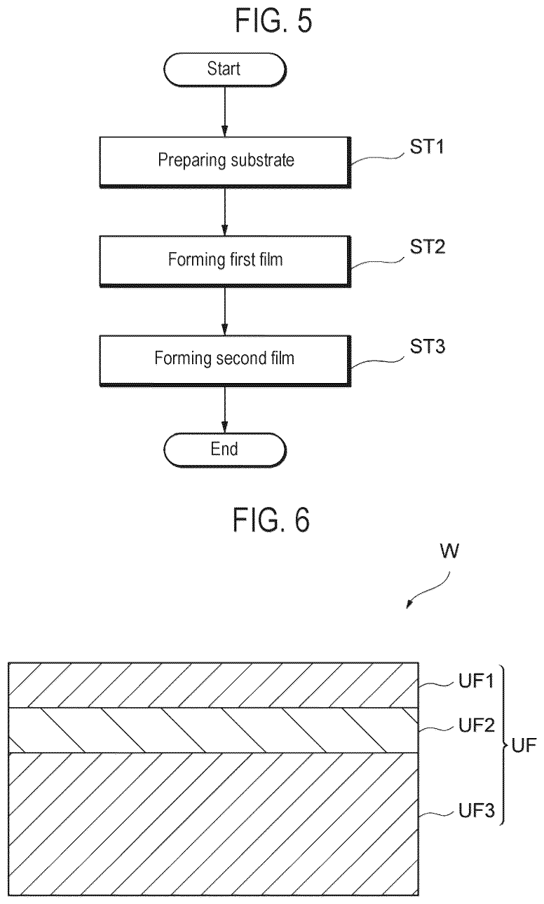

FIG. 5 is a flowchart showing a substrate processing method (hereinafter, also referred to as the present processing method) according to an exemplary embodiment. The present processing method includes Operation ST1 of providing a substrate having an underlying film, Operation ST2 of forming a first film on the underlying film, and Operation ST3 of forming a second film on the first film. In one embodiment, a process of forming the first film and the second film in Operation ST2 and Operation ST3 (hereinafter, also referred to as a “film forming process”) is performed by a dry process (hereinafter, also referred to as a “dry film formation”) using a processing gas. In one embodiment, the film forming process in Operation ST2 and Operation ST3 is performed by a wet process (hereinafter, also referred to as a “wet film formation”) using a solution. In one embodiment, the film forming process in Operation ST2 is performed by the wet film formation, and the film forming process in Operation ST3 is performed by the dry film formation. In one embodiment, the film forming process in Operation ST2 is performed by the dry film formation, and the film forming process in Operation ST3 is performed by the wet film formation.

The present processing method may be executed using any one of the above-described substrate processing systems (see FIGS. 1 to 4), or may be executed using two or more of these substrate processing systems. For example, the present processing method may be executed by the heat treatment system (see FIG. 1). Hereinafter, a case in which the controller 200 controls individual constituent elements of the heat treatment apparatus 100 to execute the present processing method with respect to the substrate W will be described as an example.

### (Operation ST1: Preparing Substrate)

First, in Operation ST1, the substrate W is loaded into the processing chamber 102 of the heat treatment apparatus 100. The substrate W is placed on the substrate support 121 by the lift pins 123. After the substrate W is placed on the substrate support 121, the temperature of the substrate support 121 is adjusted to a set temperature. The set temperature may be, for example, 300 degrees C. or lower, and may be 100 degrees C. or higher and 300 degrees C. or lower. The temperature of the substrate support 121 may be adjusted by controlling an output of at least one of the sidewall heater 104, the stage heater 120, the ceiling heater 130, or the pipe heater 160 (hereinafter, collectively referred to as “individual heaters”). In the present processing method, the temperature of the substrate support 121 may be adjusted to a set temperature before Operation ST1. That is, after the temperature of the substrate support 121 is adjusted to the set temperature, the substrate W may be placed on the substrate support 121. In subsequent operations, the temperature of the substrate support 121 may be maintained at the set temperature or may be changed.

The substrate W may be used for manufacturing semiconductor devices. The semiconductor device includes, for example, memory devices such as DRAM and 3D-NAND flash memory, and logic devices. The substrate W includes an underlying film UF. The underlying film UF may be an organic film, a dielectric film, a metal film, a semiconductor film, or a stacked film thereof, which is formed on a silicon wafer. In one embodiment, the underlying film UF includes, for example, at least one selected from a group consisting of a silicon-containing film, a carbon-containing film, and a metal-containing film.

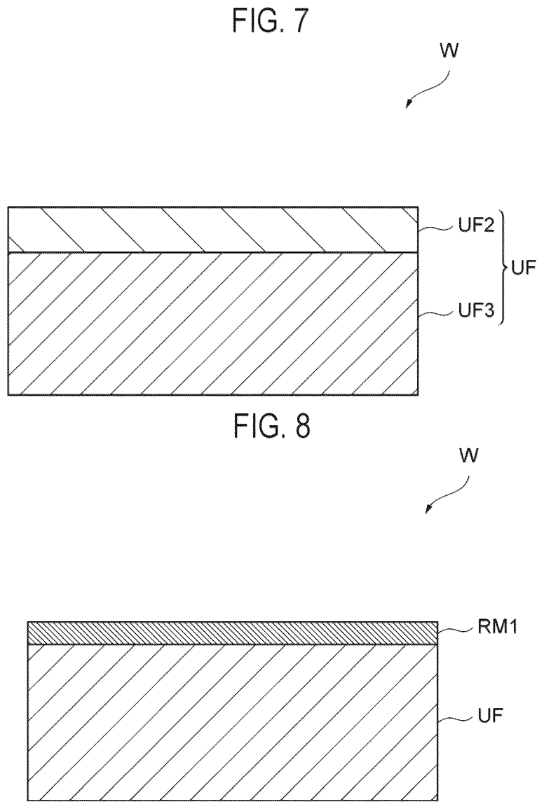

FIGS. 6 and 7 are diagrams showing an example of the underlying film UF of the substrate W, respectively. As shown in FIG. 6, the underlying film UF may be composed of a first underlying film UF1, a second underlying film UF2, and a third underlying film UF3. As shown in FIG. 7, the underlying film UF may be composed of the second underlying film UF2 and the third underlying film UF3. In one embodiment, a surface of the underlying film UF may be subjected to a surface modification treatment to enhance adhesion with a film (first film RM1) formed on the underlying film.

The first underlying film UF1 is, for example, a spin-on-glass (SOG) film, a SiC film, a SiON film, a Si-containing anti-reflective film (SiARC), or an organic film. The second underlying film UF2 is, for example, a spin-on-carbon (SOC) film, an amorphous carbon film, or a silicon-containing film. The third underlying film UF3 is, for example, a silicon-containing film. The silicon-containing film is, for example, a silicon oxide film, a silicon nitride film, a silicon oxynitride film, a silicon carbonitride film, a polycrystalline silicon film, or a carbon-containing silicon film. The third underlying film UF3 may be composed of plural kinds of stacked silicon-containing films. For example, the third underlying film UF3 may be composed of the silicon oxide film and the silicon nitride film which are alternately stacked one above another. Further, the third underlying film UF3 may be composed of the silicon oxide film and the polycrystalline silicon film which are stacked one above another. Further, the third underlying film UF3 may be a stacked film of the silicon nitride film, the silicon oxide film, and the polycrystalline silicon film. In addition, the third underlying film UF3 may be composed of the silicon oxide film and the silicon carbonitride film which are stacked one above another. Further, the third underlying film UF3 may be a stacked film of the silicon oxide film, the silicon nitride film, and the silicon carbonitride film.

A portion or the entirety of the underlying film UF may be formed inside the processing chamber 102 of the heat treatment apparatus 100, or may be formed using other systems, such as the plasma treatment system (see FIGS. 2 and 3) or the liquid treatment system (see FIG. 4).

### (Operation ST2: Forming First Film)

Subsequently, in Operation ST2, the first film RM1 is formed on the underlying film UF of the substrate W.

FIG. 8 is a diagram showing an example of a cross-sectional structure of the substrate W on which the first film RM1 is formed in Operation ST2. As shown in FIG. 8, the first film RM1 is formed on the surface of the underlying film UF. The first film RM1 is made of a material containing an element having a higher EUV absorption cross section than that of the underlying film UF. In one embodiment, the first film RM1 contains at least one metal (hereinafter, also referred to as a “first metal”) selected from a group consisting of Sn, At, Bi, Ti, Pb, Xe, I, Te, Sb, Hg, Au, Cd, In, Ge, and Ag.

In one embodiment, the first film RM1 is a metal-containing resist film. The first film RM1 may be a metal-containing resist film containing the same metal as that of a second film RM2 to be described later, or may be a metal-containing resist film containing a metal different from that of the second film RM2.

In one embodiment, the first film RM1 is a metal oxide film. In one embodiment, the first film RM1 is a metal film.

In one embodiment, the first film RM1 contains Sn. In one example, the first film RM1 is an organotin compound film having an organic substituent such as a hydrocarbon. In one example, the first film RM1 is a tin oxide (SnO, SnO₂, Sn₂O₃, and the like) film. In another example, the first film RM1 is a tin sulfide (SnS) film.

In one embodiment, a composition ratio of the metal in the first film RM1, that is, a ratio (atomic percent: at %) of a metal element in the entire first film RM1, is higher than a composition ratio of the metal in the second film RM2. For example, when the first film RM1 is the metal-containing resist film, the composition ratio of the metal in the first film RM1 may be higher than the composition ratio of the metal in the second film RM2. In one embodiment, a film density of the metal in the first film RM1 is higher than a film density of the metal in the second film RM2. In one embodiment, the films (the first film RM1 and the second film RM2) on the underlying film UF may be configured such that the film density of the metal increases toward the underlying film UF in a thickness direction.

The first film RM1 in Operation ST2 may be formed by various methods such as a chemical vapor deposition method (hereinafter, referred to as a “CVD method”) and an atomic layer deposition method (hereinafter, referred to as an “ALD method”). Such various methods for forming the first film RM1 will be described below.

### [CVD Method]

In one embodiment, in the CVD method, the first film RM1 is formed with a first processing gas including a metal-containing gas. In one embodiment, the metal-containing gas included in the first processing gas contains the first metal. In one embodiment, the first processing gas includes an oxidizing gas. The oxidizing gas may be at least one selected from a group consisting of a H₂O gas, a H₂O₂ gas, an O₃ gas, and an O₂ gas.

In one embodiment, the metal-containing gas included in the first processing gas contains at least one compound selected from a group consisting of a stannane compound, an oxygen-containing tin compound, a nitrogen-containing tin compound, and a halogenated tin compound. Examples of the stannane compound may include stannane, tetramethylstannane, tributylstannane, phenyltrimethylstannane, tetravinylstannane, dimethyldichlorostannane, butyltrichlorostannane, trichlorophenylstannane, and the like. Examples of the oxygen-containing tin compound may include tributyltinmethoxide, tert-butoxidetin, dibutyltindiacetate, triphenyltinacetate, tributyltinoxide, triphenyltinacetate, triphenyltinhydroxide, butylchlorotindihydroxide, acetylacetonatetin, and the like. Examples of the nitrogen-containing tin compound may include dimethylaminotrimethyltin, tris(dimethylamino) tert-butyltin, azidotrimethyltin, tetrakis(dimethylamino) tin, N,N′-di-tert-butyl-2,3-diamidbutanetin (II), and the like. Examples of the halogenated tin compound may include tin chloride, tin bromide, tin iodide, dimethyltindichloride, butyltintrichloride, phenyltintrichloride, and the like.

In one embodiment, in Operation ST2, the processing gas is supplied into the processing chamber 102 via the gas nozzle 141. The processing gas undergoes a chemical reaction on the substrate W and is adsorbed onto the underlying film UF. As a result, the first film RM1 is formed on the underlying film UF.

### [ALD Method]

In one embodiment, in the ALD method, the first film RM1 is formed by causing a predetermined material to be adsorbed onto and react with the underlying film UF of the substrate W in an autonomous regulation manner.

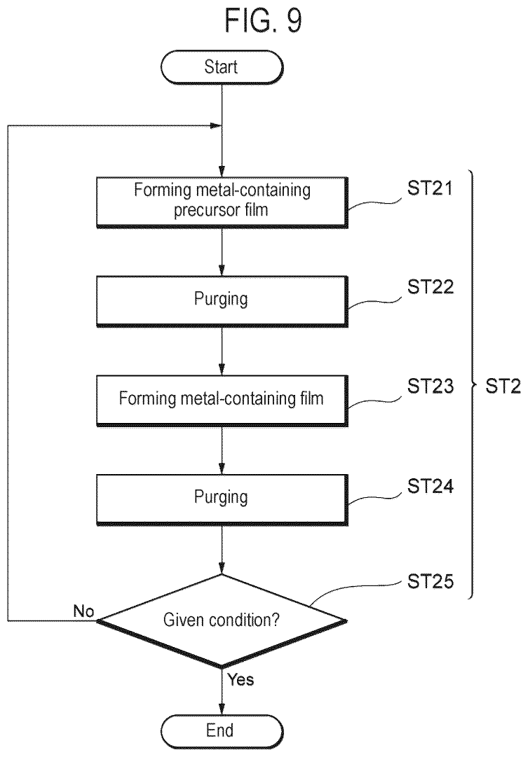

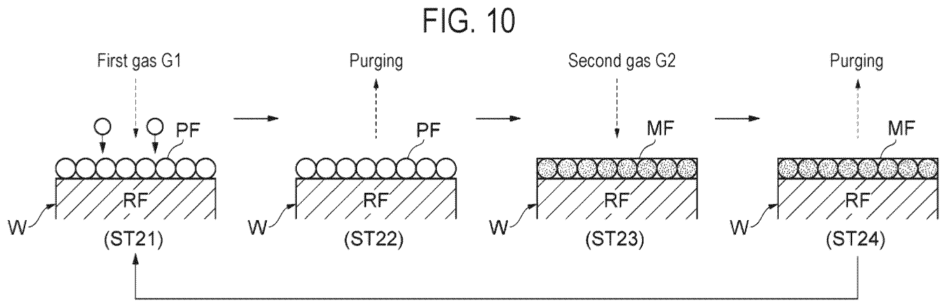

FIG. 9 is a flowchart showing an example of Operation ST2 using the ALD method. As shown in FIG. 9, Operation ST2 using the ALD method includes Operation ST21 of forming a precursor film, Operation ST22 (a first purge operation), Operation ST23 of forming a first film from the precursor film, Operation ST24 (a second purge operation), and a determination operation ST25. Operations ST22 and ST24 may be omitted. FIG. 10 is a schematic diagram showing an example of a phenomenon occurring on the surface of the substrate W in Operation ST2 using the ALD method.

In Operation ST21, as shown in FIG. 10, a first gas G1 containing a metal-containing precursor is supplied to the surface of the underlying film UF to form a precursor film PF. The metal-containing precursor contains the first metal. In one embodiment, the metal-containing precursor is a metal-containing organic precursor. In one embodiment, the metal-containing precursor contains at least one compound selected from a group consisting of the above-mentioned stannane compound, oxygen-containing tin compound, nitrogen-containing tin compound, and halogenated tin compound.

In one embodiment, in Operation ST21, the first gas G1 is supplied into the processing chamber 102 via the gas nozzle 141. Then, inside the processing chamber 102, the metal-containing precursor of the first gas G1 is adsorbed onto the surface of the underlying film UF to form a metal-containing precursor film PF. The metal-containing precursor film PF may contain, for example, a first metal species. The metal-containing precursor film PF may be a metal complex.

In Operation ST22, the gas in the processing chamber 102 is exhausted via the exhaust port 131 by the exhaust mechanism 132. At this time, an inert gas or the like may be supplied to the substrate W. As a result, an excess gas such as the metal-containing precursor may be purged. The inert gas is, for example, a noble gas such as He, Ar, Ne, Kr, or Xe, or a nitrogen gas.

In Operation ST23, as shown in FIG. 10, a second gas G2 containing an oxidizing gas is supplied to the surface of the substrate W. The second gas G2 reacts with the precursor film PF to form the first film RM1 from the precursor film PF. The oxidizing gas contained in the second gas G2 is a gas that reacts with a precursor adsorbed onto the surface of the underlying film UF. The oxidizing gas may be at least one selected from a group consisting of a H₂O gas, a H₂O₂ gas, an O₃ gas, and an O₂ gas. In one embodiment, in Operation ST213, the second gas G2 is supplied into the processing chamber 102 via the gas nozzle 141. Then, inside the processing chamber 102, the second gas G2 reacts with the precursor film PF to form the first film RM1.

In Operation ST24, the gas in the processing chamber 102 is exhausted via the exhaust port 131 by the exhaust mechanism 132. At this time, an inert gas or the like may be supplied to the substrate W. As a result, an excess gas such as the second gas G2 may be purged.

In Operation ST25, it is determined whether or not a given condition for terminating Operation ST2 is satisfied. The given condition may be that a process of one cycle including Operations ST21 to ST24 has been performed a preset number of times. The preset number of times may be once, less than five times, five or more times, or ten or more times. In Operation ST25, when it is determined that the given condition is not satisfied, the process returns to Operation ST21. When it is determined that the given condition is satisfied, Operation ST2 ends. For example, the given condition may be a condition relating to a dimension of the first film RM1 after Operation ST24. That is, after Operation ST24, it may be determined whether or not the dimension (thickness) of the first film RM1 has reached a given value or range, and the cycle including Operations ST21 to ST24 may be repeated until the dimension reaches the given value or range. The dimension of the first film RM1 may be measured by an optical measuring device. In this way, the first film RM1 is formed on the underlying film UF.

In Operation ST21, the temperature of the substrate support 121 may be controlled to a first temperature. The temperature of the substrate support 121 may be adjusted by controlling one or more outputs of the individual heaters. The first temperature may be, for example, 0 degrees C. to 250 degrees C., or 0 degrees C. to 150 degrees C. In one example, the first temperature is 150 degrees C.

In one embodiment, Operation ST2 may include an operation of heating and baking the first film RM1. The baking may be executed in an air atmosphere or an inert atmosphere. The baking may be executed by heating the substrate W to 50 degrees C. to 250 degrees C., 50 degrees C. to 200 degrees C., or 80 degrees C. to 150 degrees C. In one embodiment, the individual heaters of the heat treatment apparatus 100 may function as heating parts that perform the baking. In one embodiment, the baking may be executed using heat treatment systems other than the heat treatment apparatus 100.

### (Operation ST3: Forming Second Film)

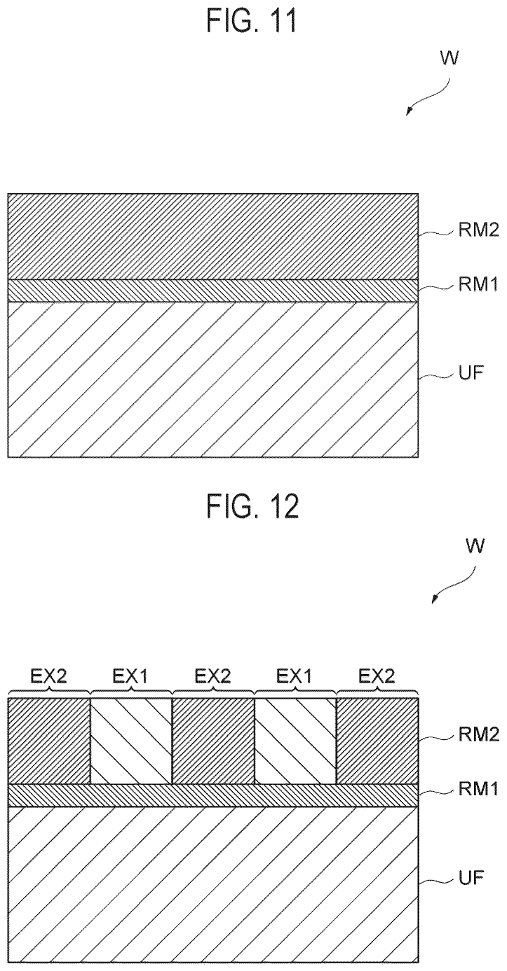

In Operation ST3, the second film RM2 is formed. FIG. 11 is a diagram showing an example of a cross-sectional structure of the substrate W on which the second film RM2 is formed in Operation ST3. As shown in FIG. 11, the second film RM2 is formed on the first film RM1. The second film RM2 is a metal-containing resist film. In one embodiment, the second film RM2 contains at least one metal (hereinafter, also referred to as a “second metal”) selected from a group consisting of Sn, Hf, and Ti. In one example, the second film RM2 may contain Sn.

In one embodiment, the kind of the metal contained in the second film RM2 is the same as that of the first film RM1. In one embodiment, the kind of the metal contained in the second film RM2 is different from that of the first film RM1. In one embodiment, the second film RM2 is made of a material having a lower secondary electron emission coefficient than the first film RM1.

In one embodiment, the second film RM2 is thicker than the first film RM1. For example, in a case in which the first film RM1 is not a resist film (for example, in a case in which the first film RM1 is a metal oxide film or a metal film), the second film RM2 may be thicker than the first film RM1.

The formation of the second film RM2 in Operation ST3 may be performed using various methods such as the CVD method, the ALD method, and the like. In one embodiment, the formation of the second film RM2 in Operation ST3 is performed using the same kind of method as the formation of the first film RM1 in Operation ST2. For example, the CVD method may be used in Operation ST2 and Operation ST3. For example, the ALD method may be used in Operation ST2 and Operation ST3.

When the CVD method is used, in Operation ST3, a second processing gas containing a metal-containing gas is supplied into the processing chamber 102 via the gas nozzle 141. In one embodiment, the metal-containing gas contained in the second processing gas contains the second metal. In one embodiment, the second processing gas contains an oxidizing gas. The oxidizing gas may be at least one selected from a group consisting of a H₂O gas, a H₂O₂ gas, an O₃ gas, an O₂ gas, and a N₂O₂ gas.

In one embodiment, the metal-containing gas contained in the second processing gas is an organometallic compound. In one embodiment, the metal-containing gas contained in the second processing gas contains at least one compound selected from a group consisting of the above-mentioned stannane compound, oxygen-containing tin compound, nitrogen-containing tin compound, and halogenated tin compound.

When the ALD method is used, in Operation ST3, a third gas G3 containing a metal-containing precursor and a fourth gas G4 containing an oxidizing gas are alternately supplied to the substrate W while appropriately performing a purge treatment like in Operation ST2. In one embodiment, the metal-containing precursor contained in the third gas G3 contains the second metal. The oxidizing gas contained in the fourth gas G4 may be at least one selected from a group consisting of a H₂O gas, a H₂O₂ gas, an O₃ gas, an O₂ gas, and a N₂O₂ gas.

In one embodiment, the metal-containing precursor contained in the third gas G3 is a metal-containing organic precursor. In one embodiment, the metal-containing precursor contained in the third gas G3 contains at least one compound selected from a group consisting of the above-mentioned stannane compound, oxygen-containing tin compound, nitrogen-containing tin compound, and halogenated tin compound.

In Operation ST3, the temperature of the substrate support 121 may be controlled to a first temperature, which is the same as that in Operation ST2, or may be controlled to a second temperature different from the first temperature. For example, the second temperature may be higher or lower than the first temperature. The temperature of the substrate support 121 may be adjusted by controlling one or more outputs of the individual heaters. The second temperature may be, for example, 0 degrees C. to 250 degrees C., or 0 degrees C. to 150 degrees C. In one example, the second temperature is 150 degrees C.

In one embodiment, Operation ST3 may include an operation of heating and baking the second film RM2. The baking may be executed in an air atmosphere or an inert atmosphere. The baking may be executed by heating the substrate W to 50 degrees C. to 250 degrees C., 50 degrees C. to 200 degrees C., or 80 degrees C. to 150 degrees C. In one embodiment, the individual heaters of the heat treatment apparatus 100 may function as heating parts that perform the baking. In one embodiment, the baking may be executed using heat treatment systems other than the heat treatment apparatus 100.

The substrate W may be subjected to an EUV exposure in a subsequent operation. In the EUV exposure, photons may decrease or decay in a lower side (side close to the first film RM1) of the second film RM2 (metal-containing resist film) in a thickness direction due to a stochastic fluctuation in photon distribution and a shallow focal depth. In view of this point, in the present processing method, the second film RM2 is formed above the first film RM1 which is made of the material containing an element having a higher EUV absorption cross section than the underlying film UF. When the first film RM1 is made of the material containing an element having a higher EUV absorption cross section than the underlying film UF, secondary electrons emitted from the first film RM1 during the EUV exposure may compensate for the decay or decrease of photons in the lower side of the second film RM2 in the thickness direction. Therefore, the present processing method may adjust an exposure sensitivity of the resist film (the second film RM2). In addition, during the EUV exposure, an exposure reaction (for example, a degree of hardening of the film) may be suppressed from weakening in the lower side of the second film RM2 in the thickness direction, which makes it possible to suppress a variation in development resistance from occurring.

As described above, when the first film RM1 is the metal-containing resist film, the composition ratio of the metal in the first film RM1 may be higher than the composition ratio of the metal in the second film RM2. As the exposure sensitivity increases, the composition ratio of the metal becomes higher. Thus, even if the photons reaching the first film RM1 during the EUV exposure are decreased or decayed as compared to the second film RM2, the decrease in the exposure sensitivity of the first film RM1 may be suppressed. Therefore, the present processing method may adjust the exposure sensitivity of the resist film (the first film RM1 and the second film RM2). In addition, during the EUV exposure, the first film RM1 may be suppressed from weakly undergoing the exposure reaction (for example, the degree of hardening of the film) as compared to the second film RM2, which makes it possible to suppress a variation in development resistance from occurring.

In one embodiment, the present processing method may be executed by the dry process using the plasma treatment system (see FIGS. 2 and 3). For example, the substrate W may be placed on the substrate support 11 inside the processing chamber 10 of the plasma treatment apparatus 1 (Operation ST1). The processing gas may be supplied from the gas supply 20 into the processing chamber 10 to form the first film RM1 and the second film RM2 (Operation ST2 and Operation ST3).

In the case of using the plasma treatment system, the above-mentioned ALD method or CVD method may be used in Operation ST21 and Operation ST22. The temperature of the substrate support 11 may be adjusted by controlling the pressure of the heat-transfer gas (for example, He) between the temperature adjustment module or the electrostatic chuck 1111 and the back surface of the substrate W. In Operation ST2 and/or Operation ST3, plasma may be generated from the processing gas, or no plasma may be generated. As in the case of using the heat treatment system (see FIG. 1), Operation ST2 and/or Operation ST3 may include an operation of heating the substrate W to perform a baking process. The baking process may be executed using, for example, the heat treatment system.

In one embodiment, the present processing method may be executed by the wet process using the liquid treatment system (see FIG. 4). That is, the substrate W may be placed on the spin chuck 311 inside the processing chamber 310 of the liquid treatment apparatus 300 (Operation ST1). A film-forming solution may be applied onto the substrate W from the processing-liquid supply nozzle 331 to form the first film RM1 and the second film RM2 (Operation ST2 and Operation ST3).

The film-forming solution used in Operation ST2 contains the first metal. In one embodiment, the solution contains at least one compound selected from a group consisting of the above-mentioned stannane compound, oxygen-containing tin compound, nitrogen-containing tin compound, and halogenated tin compound.

The film-forming solution used in Operation ST3 contains the second metal. In one embodiment, the solution contains at least one compound selected from a group consisting of the above-mentioned stannane compound, oxygen-containing tin compound, nitrogen-containing tin compound, and halogenated tin compound.

In the case of using the liquid treatment system, Operation ST21 and/or Operation ST22 may include an operation of heating and baking the substrate W after the solution is applied onto the substrate W. In one embodiment, the baking may be performed using, for example, the heat treatment system (see FIG. 1). The baking may be performed in an air atmosphere or an inert atmosphere. The baking may be performed by heating the substrate W to 50 degrees C. to 250 degrees C., 50 degrees C. to 200 degrees C., or 80 degrees C. to 150 degrees C.

In one embodiment, the film forming process of the present processing method may be performed by both the dry process using the heat treatment system (see FIG. 1) or the plasma treatment system (see FIGS. 2 and 3) and the wet process using the liquid treatment system (see FIG. 4). For example, the first film RM1 may be formed by the dry process in Operation ST2, and the second film RM2 may be formed by the wet process in Operation ST3. In this case, since the first film RM1 is formed at a stage of performing the wet film formation in Operation ST3, it is possible to suppress the solution (resist liquid) for forming the second film RM2 from permeating into the underlying film UF. In addition, for example, the first film RM1 may be formed by the wet process in Operation ST2, and the second film RM2 may be formed by the dry process in Operation ST3.

In one embodiment, the process of forming the first film RM1 in the present processing method may be executed using a PVD apparatus. For example, when the first film RM1 is a metal film or a metal oxide film, the first film may be formed by forming the metal on the underlying film UF by vacuum deposition, sputtering or the like using the PVD apparatus.

In one embodiment, the present processing method includes an operation of exposing the substrate W to EUV after Operation ST3. EUV has a wavelength in a range of, for example, 10 to 20 nm. EUV may have a wavelength in a range of 11 to 14 nm. In one example, EUV may have a wavelength of 13.5 nm.

FIG. 12 is a diagram showing an example of a cross-sectional structure of the substrate W exposed to EUV. As shown in FIG. 12, an exposed first region EX1 and an unexposed second region EX2 are formed in the second film RM2. As described above, the secondary electrons emitted from the first film RM1 during the EUV exposure may compensate for the decay or decrease of photons in the lower side of the second film RM2 in the thickness direction. This makes the first region EX1 of the second film RM2 to uniformly undergo the exposure reaction (for example, the degree of hardening of the film) in the thickness direction.

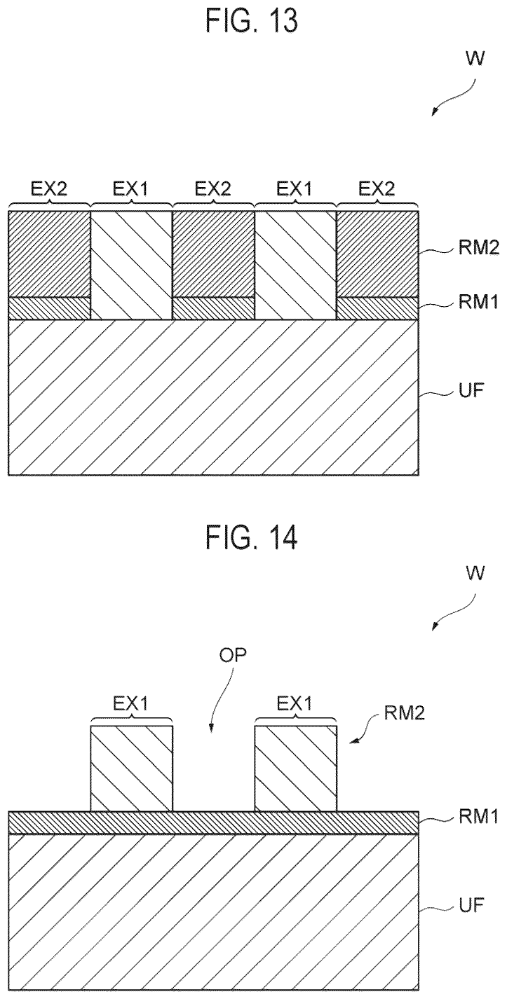

FIG. 13 is a diagram showing another example of the cross-sectional structure of the substrate W exposed to EUV. FIG. 13 shows a case in which the first film RM1 is a metal-containing resist film. As shown in FIG. 13, the first film RM1 and the second film RM2 have an exposed first region EX1 and an unexposed second region EX2. In one embodiment, the composition ratio of the metal in the first film RM1 is higher than that in the second film RM2. In this case, even if the photons reaching the first film RM1 during the EUV exposure are decreased or decayed as compared to the second film RM2, the decrease in the exposure sensitivity of the first film RM1 may be suppressed. This makes the exposure reaction (for example, the degree of hardening of the film) uniform between the first region EX1 of the first film RM1 and the first region EX1 of the second film RM2.

In one embodiment, the present processing method further includes an operation of developing the substrate W after the exposure to selectively remove the first region or the second region from the second film RM2. When the first film RM1 is the metal-containing resist film, the first film RM1 may also be developed. In one embodiment, such a development process is performed by a wet process using a developing solution (hereinafter, also referred to as a “wet development”). In one embodiment, the development process is performed by a dry process using a developing gas (hereinafter, also referred to as a “dry development”). In one embodiment, the development process may be performed by both the wet development and the dry development. For example, when the first film RM1 is the metal-containing resist film, the second film RM2 may be subjected to the wet development and the first film RM1 may be subjected to the dry development.

When performing the dry development on the metal-containing resist film RM, at least one developing gas is supplied into the processing chamber 102 via the gas nozzle 141. In one embodiment, the developing gas may include at least one selected from a group consisting of hydrogen bromide (HBr), hydrogen fluoride (HF), hydrogen chloride (HCl), boron trichloride (BCl₃), organic acid (for example, carboxylic acid or alcohol), and a β-dicarbonyl compound. For example, the carboxylic acid as the developing gas may include at least one selected from a group consisting of formic acid (HCOOH), acetic acid (CH₃COOH), trichloroacetic acid (CCl₃COOH), monofluoroacetic acid (CFH₂COOH), difluoroacetic acid (CF₂FCOOH), trifluoroacetic acid (CF₃COOH), chloro-difluoroacetic acid (CClF₂COOH), sulfur-containing acetic acid, thioacetic acid (CH₃COSH), thioglycolic acid (HSCH₂COOH), trifluoroacetic anhydride ((CF₃CO)₂O), and acetic anhydride ((CH₃CO)₂O). For example, the alcohol as the developing gas may include nonafluoro-tert-butyl alcohol ((CF₃)₃COH). For example, the β-dicarbonyl compound as the developing gas may be acetylacetone (CH₃C(O)CH₂C(O)CH₃), trichloroacetylacetone (CCl₃C(O)CH₂C(O)CH₃), hexachloroacetylacetone (CCl₃C(O)CH₂C(O)CCl₃), trifluoroacetylacetone (CF₃C(O)CH₂C(O)CH₃), or hexafluoroacetylacetone (HFAc, CF₃C(O)CH₂C(O)CF₃). In one embodiment, the development may be performed by a thermal reaction between the developing gas and the metal-containing resist film RM, or by a chemical reaction between chemical species from plasma generated from the developing gas and the metal-containing resist film RM.

FIG. 14 is a diagram showing an example of a cross-sectional structure of the substrate W after the development. FIG. 14 shows an example in which the substrate W after the exposure shown in FIG. 12 is developed to selectively remove the second region from the second film RM2. As shown in FIG. 14, an opening OP is formed in the second film RM2. The opening OP is defined by side surfaces of adjacent first regions EX1 of the second film RM2. The opening OP is a space on the first film RM1 surrounded by the side surfaces. The opening OP has a shape corresponding to the first region EX1 as viewed from the plane of the substrate W (resultantly, a shape corresponding to an exposure mask pattern used for the EUV exposure). Examples of the shape may include a circle, an ellipse, a rectangle, a line, or a combination of at least one of these. A plurality of openings OP may be formed in the second film RM2. Each of the plurality of openings OP may have a linear shape. The plurality of openings OP may be arranged at regular intervals to form a line-and-space pattern. Further, the plurality of openings OP may be arranged in a lattice pattern to form a pillar pattern.

In one embodiment, the present processing method may further include an operation of etching the first film RM1 using the second film RM2 as a mask after developing the second film RM2. As a result, a recess is formed in the first film RM1 based on the shape of the opening OP. In addition, in the operation of etching the first film RM1, a portion of the underlying film UF may be etched.

The etching of the first film RM1 may be performed by the wet process, the dry process, or both the wet process and the dry process. When the etching of the first film RM1 is performed by the dry process, the above-mentioned developing gas may be used as an etching gas. The etching of the first film RM1 may be performed in the same chamber as or a different chamber from that used in the above-mentioned developing process.

In one embodiment, the first film RM1 and the second film RM2 are different from each other in the kind and composition ratio of the metal contained in the respective films. For this reason, when developing the second film RM2 or etching the first film RM1, a boundary region between the first film RM1 and the second film RM2 may be scraped horizontally, resulting in a groove or the like. Therefore, the development of the second film RM2 and/or the etching of the first film RM1 may be performed while protecting sidewalls of the second film RM2 and/or the first film RM1. For example, when developing the second film RM2 and etching the first film RM1 by the dry process, a gas having a sidewall protection effect (hereinafter, also referred to as a “protective gas”) may be added to the above-mentioned developing gas or etching gas. By adding the protective gas, a passivation layer is formed on the sidewalls of the second film RM2 and/or the first film RM1, so that the horizontal scraping of these films may be suppressed.

An oxygen-containing gas may be used as the protective gas. In one example, the protective gas may be at least one selected from a group consisting of O₂, CO₂, CO, COS, SO₂, and H₂O. When the oxygen-containing gas is added as the protective gas, a layer containing Sn—O bonds may be formed on the sidewalls of the second film RM2 and/or the first film RM1.

In addition, a gas containing carbon and/or silicon may be used as the protective gas. For example, at least one selected from a group consisting of hydrocarbon, fluorocarbon, and hydrofluorocarbon may be used as the carbon-containing gas. For example, SiCl₄ may be used as the silicon-containing gas. In addition, aminotin or the like may be used as the protective gas. With these protective gases, a carbon and/or silicon protective layer may be formed on the sidewalls of the second film RM2 and/or the first film RM1.

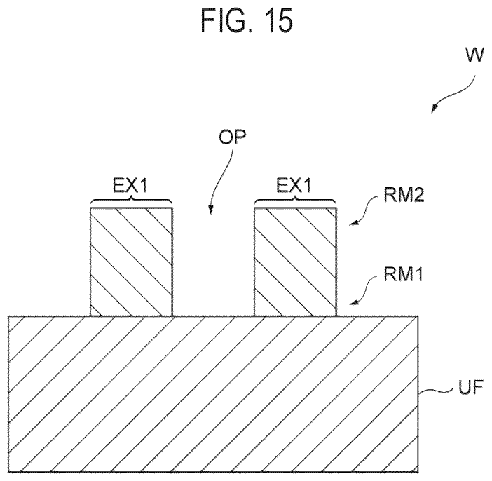

FIG. 15 is a diagram showing another example of the cross-sectional structure of the substrate W after the development. FIG. 15 shows an example in which the substrate W after the exposure shown in FIG. 13 is developed to selectively remove the second region from the first film RM1 and the second film RM2. As shown in FIG. 15, an opening OP is formed in the first film RM1 and the second film RM2. The opening OP is defined by side surfaces of adjacent first regions EX1 of the first film RM1 and the second film RM2. The opening OP is a space on the underlying film UF surrounded by the side surfaces. The opening OP has a shape corresponding to the first regions EX1 when viewed from the plane of the substrate W (resultantly, a shape corresponding to an exposure mask pattern used for the EUV exposure). Examples of the shape may include a circle, an ellipse, a rectangle, a line, or a combination of at least one of these. A plurality of openings OP may be formed in the second film RM2. Each of the plurality of openings OP may have a linear shape. The plurality of openings OP may be arranged at regular intervals to form a line-and-space pattern. Further, the plurality of openings OP may be arranged in a lattice pattern to form a pillar pattern.

In one embodiment, the present processing method may further include an operation of etching the underlying UF after the development. In one embodiment, the underlying UF is etched using the first film RM1 and the second film RM2 as a mask. As a result, a portion of the underlying UF that is not covered by the first film RM1 and the second film RM2 (a portion exposed to the opening OP in the first film RM1 and the second film RM2) is etched in a depth direction.

The etching of the underlying UF may be performed by, for example, the plasma treatment system (see FIGS. 2 and 3). In this case, first, a processing gas is supplied from the shower head 13 in the plasma treatment apparatus 1 into the processing chamber 10. The processing gas includes a gas that generates active species required for etching the underlying UF.

Subsequently, one or more RF signals are supplied from the RF power supply 31 to the upper electrode and/or the lower electrode. As a result, plasma is generated from the processing gas inside the plasma processing space 10s. In addition, a bias RF signal may be supplied to the lower electrode of the substrate support 11. By supplying the bias RF signal to the lower electrode, a bias potential is generated on the substrate W, and ion components in the formed plasma may be drawn into the substrate W. This may promote the etching of the underlying film UF. The method of etching the underlying film UF is not particularly limited.

### <Configuration Example of Substrate Processing System>

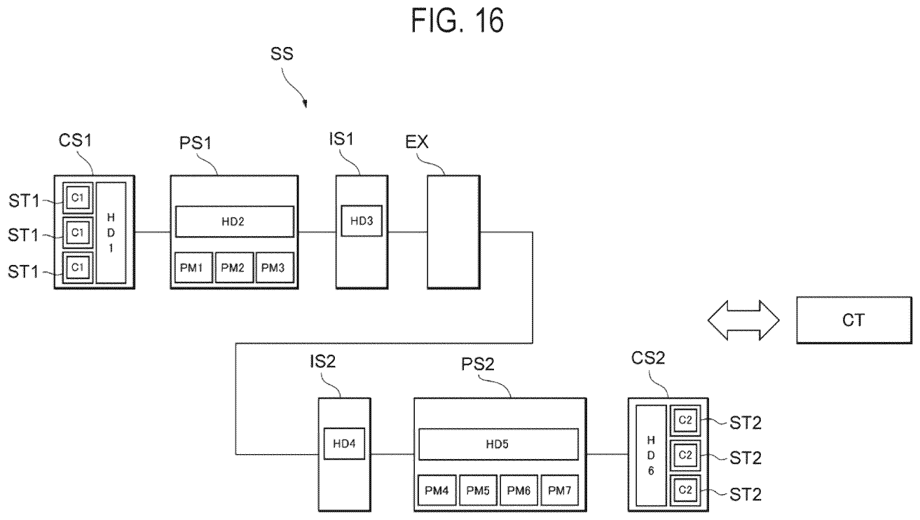

FIG. 16 is a block diagram for explaining an exemplary configuration of a substrate processing system SS according to an exemplary embodiment. The substrate processing system SS includes a first carrier station CS1, a first processing station PS1, a first interface station IS1, an exposure device EX, a second interface station IS2, a second processing station PS2, a second carrier station CS2, and a controller CT.

The first carrier station CS1 loads and unloads a first carrier C1 with respect to an external system of the substrate processing system SS. The first carrier station CS1 is provided with a stage including a plurality of first stage plates ST1. The first carrier C1, which is empty or holds a plurality of substrates W, is placed on each of the first stage plates ST1. The first carrier C1 includes a housing capable of accommodating the plurality of substrates W therein. In one example, the first carrier C1 is a front opening unified pod (FOUP).

Further, the first carrier station CS1 transfers the substrate W between the first carrier C1 and the first processing station PS1. The first carrier station CS1 further includes a first transfer device HD1. The first transfer device HD1 is provided in the first carrier station CS1 so as to be located between the stage and the first processing station PS1. The first transfer device HD1 transfers and delivers the substrate W between the first carrier C1 on each first stage plate ST1 and a second transfer device HD2 of the first processing station PS1. The substrate processing system SS may further include a load lock module. The load lock module may be provided between the first carrier station CS1 and the first processing station PS1. The load lock module may switch its internal pressure to atmospheric pressure or vacuum. The “atmospheric pressure” may be an internal pressure of the first transfer device HD1. The “vacuum” is a pressure lower than the atmospheric pressure, and may be a medium vacuum of, for example, 0.1 Pa to 100 Pa. An interior of the second transfer device HD2 may be kept at the atmospheric pressure or vacuum. For example, the load lock module may transfer the substrate W from the first transfer device HD1, which is kept at the atmospheric pressure, to the second transfer device HD2, which is kept at the vacuum. Further, the load lock module may transfer the substrate W from the second transfer device HD2, which is kept at the vacuum, to the first transfer device HD1, which is kept at the atmospheric pressure.

The first processing station PS1 performs various processes on the substrate W. In one embodiment, the first processing station PS1 includes a pre-processing module PM1, a resist film forming module PM2, and a first heat treatment module PM3 (hereinafter, collectively referred to as a “first substrate processing module PMa”). Further, the first processing station PS1 includes the second transfer device HD2 that transfers the substrate W. The second transfer device HD2 transfers and delivers the substrate W between two designated first substrate processing modules PMa, and between the first processing station PS1 and the first carrier station CS1 or the first interface station IS1.

In the pre-processing module PM1, the substrate W is subjected to a pre-processing. In one embodiment, the pre-processing module PM1 includes a temperature adjustment unit for adjusting a temperature of the substrate W, a high-precision temperature adjustment unit for adjusting the temperature of the substrate W with high precision, and an underlying film forming unit for forming a portion or all of the underlying film on the substrate W. In one embodiment, the pre-processing module PM1 includes a surface modification treatment unit for performing a surface modification treatment on the substrate W. Each treatment unit of the pre-processing module PM1 may include the heat treatment apparatus 100 (see FIG. 1), the plasma treatment apparatus 1 (see FIGS. 2 and 3), and/or the liquid treatment apparatus 300 (see FIG. 4).

In the resist film forming module PM2, a resist film is formed on the substrate W. In one embodiment, the resist film forming module PM2 includes a dry coating unit. The dry coating unit forms the resist film on the substrate W using the dry process such as a vapor phase deposition method. In one example, the dry coating unit includes a CVD apparatus or an ALD apparatus for chemically depositing the resist film on the substrate W disposed in a chamber, or a PVD apparatus for physically depositing the resist film. The dry coating unit may be the heat treatment apparatus 100 (see FIG. 1) or the plasma treatment apparatus 1 (see FIGS. 2 and 3).

In one embodiment, the resist film forming module PM2 includes a wet coating unit. The wet coating unit forms the resist film on the substrate W using a wet process such as a liquid phase deposition method. In one example, the wet coating unit may be the liquid treatment apparatus 300 (see FIG. 4).

In one embodiment, examples of the resist film forming module PM2 may include both the wet coating unit and the dry coating unit.

In the first heat treatment module PM3, the substrate W is subjected to heat treatment. In one embodiment, the first heat treatment module PM3 includes at least one of a pre-bake (Post Apply Bake: PAB) unit that performs the heat treatment on the substrate W on which the resist film is formed, a temperature adjustment unit that adjusts the temperature of the substrate W, or a high-precision temperature adjustment unit that adjusts the temperature of the substrate W with high precision. Each of these units may have one or more heat treatment apparatuses. In one example, the plurality of heat treatment apparatuses may be stacked one above another. The heat treatment apparatus may be, for example, the heat treatment apparatus 100 (see FIG. 1). The heat treatment may be performed at a predetermined temperature using a predetermined gas.

The first interface station IS1 includes a third transfer device HD3. The third transfer device HD3 transfers and delivers the substrate W between the first processing station PS1 and the exposure device EX. The third transfer device HD3 includes a housing that accommodates the substrate W, and may be configured to be capable of controlling a temperature, humidity, pressure, and the like of an interior of the housing.

The exposure device EX exposes the resist film on the substrate W using an exposure mask (reticle). The exposure device EX may be, for example, an EUV exposure device including a light source that generates EUV light.

The second interface station IS2 includes a fourth transfer device HD4. The fourth transfer device HD4 transfers and delivers the substrate W between the exposure device EX and the second processing station PS2. The fourth transfer device HD4 includes a housing that accommodates the substrate W, and may be configured to be capable of controlling a temperature, humidity, pressure, and the like of an interior of the housing.

The second processing station PS2 performs various processes on the substrate W. In one embodiment, the second processing station PS2 includes a second heat treatment module PM4, a measurement module PM5, a development module PM6, and a third heat treatment module PM7 (hereinafter, collectively referred to as a “second substrate processing module PMb”). Further, the second processing station PS2 includes a fifth transfer device HD5 for transferring the substrate W. The fifth transfer device HD5 transfers and delivers the substrate W between two designated second substrate processing modules PMb, and between the second processing station PS2 and the second carrier station CS2 or the second interface station IS2.

In the second heat treatment module PM4, the substrate W is subjected to heat treatment. In one embodiment, the second heat treatment module PM4 includes at least one of a post exposure bake (PEB) unit that performs the heat treatment on the substrate W after exposure, a temperature adjustment unit that adjusts the temperature of the substrate W, or a high-precision temperature adjustment unit that adjusts the temperature of the substrate W with high precision. Each of these units may have one or more heat treatment apparatuses. In one example, the plurality of heat treatment apparatuses may be stacked one above another. The heat treatment apparatus may be, for example, the heat treatment apparatus 100 (see FIG. 1). The heat treatment may be performed at a predetermined temperature using a predetermined gas.

In the measurement module PM5, various measurements are performed on the substrate W. In one embodiment, the measurement module PM5 is provided with a capturing unit including a stage on which the substrate W is placed, a capturing device, an illumination device, and various sensors (a temperature sensor, a reflectance measurement sensor, and the like). The capturing device may be, for example, a CCD camera that captures an image of an appearance of the substrate W. Alternatively, the capturing device may be a hyper-spectral camera that captures an image by dispersing light on a wavelength basis. The hyper-spectral camera may measure at least one of a pattern shape, a dimension, a film thickness, a composition, or a film density of the resist film.

In the development module PM6, the substrate W is subjected to development treatment. In one embodiment, the development module PM6 includes a dry development unit that performs the dry development on the substrate W. The dry development unit may be, for example, the heat treatment apparatus 100 (see FIG. 1) or the plasma treatment apparatus 1 (see FIGS. 2 and 3). In one embodiment, the development module PM6 includes a wet development unit that performs the wet development on the substrate W. The wet development unit may be, for example, the liquid treatment apparatus 300 (see FIG. 4). In one embodiment, the development module PM6 includes both the dry development unit and the wet development unit.

In the third heat treatment module PM7, the substrate W is subjected to heat treatment. In one embodiment, the third heat treatment module PM7 includes at least one of a post-bake (PB) unit that heat-treats the substrate W after development, a temperature adjustment unit that adjusts the temperature of the substrate W, and a high-precision temperature adjustment unit that adjusts the temperature of the substrate W with high precision. Each of these units may have one or more heat treatment apparatuses. In one example, the plurality of heat treatment apparatuses may be stacked one above another. The heat treatment apparatus may be, for example, the heat treatment apparatus 100 (see FIG. 1). The heat treatment may be performed at a predetermined temperature using a predetermined gas.

The second carrier station CS2 loads and unloads a second carrier C2 with respect to an external system of the substrate processing system SS. A configuration and function of the second carrier station CS2 may be the same as those of the above-described first carrier station CS1.

The controller CT controls individual constituent elements of the substrate processing system SS to execute a given processing on the substrate W. The controller CT stores a recipe in which process procedures, process conditions, transfer conditions, and the like are set, and controls the individual constituent elements of the substrate processing system SS to execute the given processing on the substrate W according to the recipe. The controller CT may execute some or all of the functions of the controllers (the controller 200, the controller 2, and the controller 400 shown in FIGS. 1 to 4).

### <Example of Substrate Processing Method>

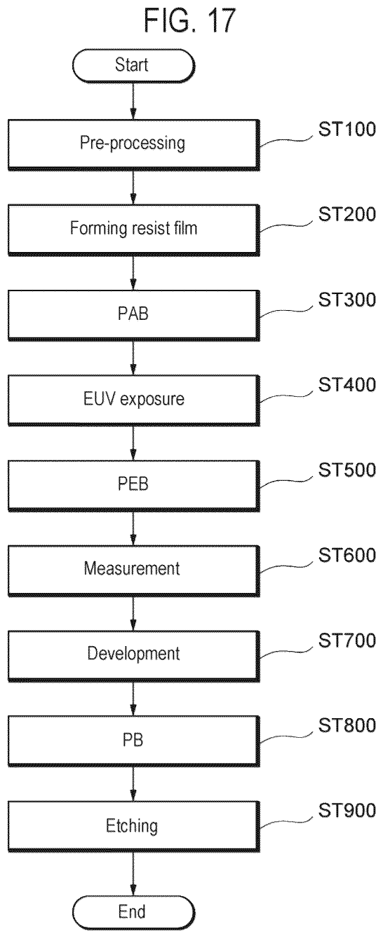

FIG. 17 is a flowchart showing the substrate processing method (hereinafter, also referred to as a “method MT”) according to an exemplary embodiment. As shown in FIG. 17, the method MT includes Operation ST100 of performing the pre-processing on the substrate, Operation ST200 of forming the resist film on the substrate, Operation ST300 of performing the heat treatment (pre-bake: PAB) on the substrate on which the resist film is formed, Operation ST400 of performing the EUV exposure on the substrate, Operation ST500 of performing the heat treatment (post exposure bake: PEB) on the substrate after the exposure, Operation ST600 of measuring the substrate, Operation ST700 of developing the resist film on the substrate, Operation ST800 of performing the heat treatment (post-bake: PB) on the substrate after the development, and Operation ST900 of etching the substrate. The method MT may not include at least one of Operations above. For example, the method MT may not include Operation ST600, and Operation ST700 may be performed after Operation ST500.

The method MT may be executed using the substrate processing system SS shown in FIG. 16. Hereinafter, a case in which the controller CT of the substrate processing system SS controls the individual constituent elements of the substrate processing system SS to execute the method MT on the substrate W will be described as an example.

### (Operation ST100: Pre-Processing)

First, the first carrier C1 accommodating the plurality of substrates W is loaded into the first carrier station CS1 of the substrate processing system SS. The first carrier C1 is placed on the first stage plate ST1. Subsequently, the first transfer device HD1 sequentially picks up the individual substrates W from the first carrier C1 and delivers the same to the second transfer device HD2 of the first processing station PS1. The substrate W is transferred to the pre-processing module PM1 by the second transfer device HD2. The pre-processing module PM1 performs the pre-processing on the substrate W. For example, the pre-processing may include at least one of adjusting the temperature of the substrate W, forming a portion or the entirety of the underlying film on the substrate W, heating the substrate W, and adjusting the temperature of the substrate W with high-precision. The pre-processing may include a surface modification treatment on the substrate W.

### (Operation ST200: Formation of Resist Film)

Subsequently, the substrate W is transferred to the resist film forming module PM2 by the second transfer device HD2. The resist film is formed on the substrate W by the resist film forming module PM2. In one embodiment, the resist film is formed by a wet process such as a liquid phase deposition method. For example, the resist film is formed by spin-coating the resist film on the substrate W using the wet coating unit of the resist film forming module PM2. In one embodiment, the resist film is formed on the substrate W by a dry process such as a vapor phase deposition method. For example, the resist film is formed by vapor-depositing the resist film on the substrate W using the dry coating unit of the resist film forming module PM2. The formation of the resist film in Operation ST200 may be performed by using the present processing method (see FIG. 5). That is, the first film RM1 may be formed on the substrate W, and then the second film RM2 formed of the metal-containing resist film may be formed on the first film RM1. The first film RM1 may or may not be the metal-containing resist film.

The resist film may be formed on the substrate W using both the dry process and the wet process. For example, after the first resist film is formed on the substrate W using the dry process, the second resist film may be formed on the first resist film using the wet process. In this case, film thicknesses, materials, and/or compositions of the first resist film and the second resist film may be identical to or different from each other.

### (Operation ST300: PAB)

Subsequently, the substrate W is transferred to the first heat treatment module PM3 by the second transfer device HD2. The substrate W is subjected to the heat treatment (pre-bake: PAB) by the first heat treatment module PM3. The pre-bake may be performed in an air atmosphere or an inert atmosphere. In addition, the pre-bake may be performed by heating the substrate W to 50 degrees C. or higher, or 80 degrees C. or higher. A heating temperature of the substrate W may be 250 degrees C. or lower, 200 degrees C. or lower, or 150 degrees C. or lower. In one example, the heating temperature of the substrate may be 50 degrees C. or higher and 250 degrees C. or lower. When the resist film is formed by the dry process in Operation ST200, in one embodiment, the pre-bake may be performed continuously in the dry coating unit that performed Operation ST200. In one embodiment, after the pre-bake, a process (Edge Bead Removal: EBR) may be performed to remove the resist film at an end portion of the substrate W.

### (Operation ST400: EUV Exposure)

Subsequently, the substrate W is delivered to the third transfer device HD3 of the first interface station IS1 by the second transfer device HD2. Then, the substrate W is transferred to the exposure device EX by the third transfer device HD3. The substrate W is exposed to EUV light via an exposure mask (reticle) in the exposure device EX. As a result, a first region which is exposed to EUV and a second region which is not exposed to EUV are formed on the substrate W in conformity to a pattern of the exposure mask (reticle). In one embodiment, a film thickness of the first region may be smaller than a film thickness of the second region.

### (Operation ST500: PEB)

Subsequently, the substrate W is delivered from the fourth transfer device HD4 of the second interface station IS2 to the fifth transfer device HD5 of the second processing station PS2. Then, the substrate W is transferred to the second heat treatment module PM4 by the fifth transfer device HD5. Thereafter, the substrate W is subjected to the heat treatment (post exposure bake: PEB) in the second heat treatment module PM4. The post exposure bake may be performed in an air atmosphere. The post exposure bake may be performed by heating the substrate W to 180 degrees C. or higher and 250 degrees C. or lower.

### (Operation ST600: Measurement)

Subsequently, the substrate W is transferred to the measurement module PM5 by the fifth transfer device HD5. The measurement module PM5 measures the substrate W. The measurement may be an optical measurement or another measurement. In one embodiment, the measurement performed by the measurement module PM5 includes measuring an appearance and/or dimensions of the substrate W using the CCD camera. In one embodiment, the measurement performed by the measurement module PM5 includes measuring at least one of a pattern shape, dimensions, a film thickness, a composition, and a film density of the resist film using the hyper-spectral camera (hereinafter, also referred to as “pattern shape and the like”).

In one embodiment, the controller CT determines the presence or absence of an exposure abnormality of the substrate W based on the measured appearance, dimensions, and/or pattern shape and the like of the substrate W. In one embodiment, when the controller CT determines that the exposure abnormality has occurred, the substrate W may be reworked or discarded without performing the development process in Operation ST700. The rework of the substrate W may be performed by removing the resist on the substrate W and forming a resist film again in Operation ST200. The rework after the development may cause damage to the substrate W. However, by performing the rework before the development, the damage to the substrate W may be avoided or suppressed.

### (Operation ST700: Development)

Subsequently, the substrate W is transferred to the development module PM6 by the fifth transfer device HD5. In the development module PM6, the resist film on the substrate W is developed. Either the first region exposed to EUV or the second region not exposed to EUV is selectively removed by the development process. The development process may be performed by the dry development or the wet development. The development process may be performed by a combination of the dry development and the wet development. After or during the development process, a desorption process may be performed one or more times. The desorption process includes descumming or smoothing the surface of the resist film and/or the surface of the underlying film UF with an inert gas such as helium or plasma of the inert gas.

### (Operation ST800: PB)

Subsequently, the substrate W is transferred by the fifth transfer device HD5 to the third heat treatment module PM7 where the substrate W is subjected to the heat treatment (post-bake). The post-bake may be performed in an air atmosphere or in a depressurized atmosphere containing N₂ or O₂. In addition, the post-bake may be performed by heating the substrate W to 150 degrees C. or higher and 250 degrees C. or lower. The post-bake may be performed in the second heat treatment module PM4 instead of the third heat treatment module PM7. In one embodiment, after the post-bake, the substrate W may be optically measured by the measurement module PM5. Such a measurement may be performed in addition to or instead of the measurement in Operation ST600. In one embodiment, the controller CT determines the presence or absence of abnormality such as defects, scratches, and adhesion of foreign matters in the developed pattern of the substrate W based on the measured appearance, dimensions, and/or pattern shape and the like of the substrate W. In one embodiment, when the controller CT determines that the abnormality has occurred, the substrate W may be reworked or discarded without performing the etching in Operation ST900. In one embodiment, when the controller CT determines that the abnormality has occurred, opening dimensions of the resist film on the substrate W may be adjusted using the dry coating unit (the CVD apparatus, the ALD apparatus, or the like).

### (Operation ST900: Etching)

After Operation ST800 is performed, the substrate W is delivered to the sixth transfer device HD6 of the second carrier station CS2 by the fifth transfer device HD5, and is transferred to the second carrier C2 of the second stage plate ST2 by the sixth transfer device HD6. After that, the second carrier C2 is transferred to a plasma treatment system (not shown). The plasma treatment system may be, for example, the plasma treatment system shown in FIGS. 2 and 3. In the plasma treatment system, the underlying film UF of the substrate W is etched using the developed resist film as a mask. In this way, the method MT ends. In addition, in the case in which the resist film is developed using the plasma treatment apparatus in Operation ST700, the etching may be performed subsequently in the plasma processing chamber of the plasma treatment apparatus. In addition, in the case in which the second processing station PS2 includes the plasma treatment module in addition to the development module PM6, the etching may be performed in the plasma treatment module. The above-described desorption process may be performed one or more times before or during the etching.

The embodiment of the present disclosure further includes the following aspects.

### [Supplementary Note 1]

A substrate processing method includes:
a preparation operation of preparing a substrate having an underlying film;
a first film-formation operation of forming a first film on the underlying film, the first film being made of a material containing an element having a higher EUV absorption cross section than the underlying film; and
a second film-formation operation of forming a second film on the first film, the second film being a metal-containing resist film.

### [Supplementary Note 2]

In the substrate processing method of Supplementary Note 1 above, the first film contains at least one metal selected from a group consisting of Sn, At, Bi, Ti, Pb, Xe, I, Te, Sb, Hg, Au, Cd, In, Ge, and Ag.

### [Supplementary Note 3]

In the substrate processing method of Supplementary Note 1 or 2 above, the first film contains Sn.

### [Supplementary Note 4]

In the substrate processing method of Supplementary Note 2 or 3 above, a composition ratio of the metal in the first film is higher than a composition ratio of a metal in the second film.

### [Supplementary Note 5]

In the substrate processing method of any one of Supplementary Notes 1 to 4 above, the first film is a metal-containing resist film.

### [Supplementary Note 6]

In the substrate processing method of any one of Supplementary Notes 1 to 6 above, in the first film-formation operation, the first film is formed using a dry process.

### [Supplementary Note 7]

In the substrate processing method of any one of Supplementary Notes 1 to 6 above, in the first film-formation operation, the first film is formed using a wet process.

### [Supplementary Note 8]

In the substrate processing method of any one of Supplementary Notes 1 to 7 above, the second film contains at least one metal selected from a group consisting of Sn, Hf, and Ti.

### [Supplementary Note 9]

In the substrate processing method of any one of Supplementary Notes 1 to 8 above, the second film contains Sn.

### [Supplementary Note 10]

In the substrate processing method of any one of Supplementary Notes 1 to 9 above, the second film is thicker than the first film.

### [Supplementary Note 11]

In the substrate processing method of any one of Supplementary Notes 1 to 10 above, in the second film-formation operation, the second film is formed using a dry process.

### [Supplementary Note 12]

In the substrate processing method of any one of Supplementary Notes 1 to 11 above, in the second film-formation operation, the second film is formed using a wet process.

### [Supplementary Note 13]

The substrate processing method of any one of Supplementary Notes 1 to 12 above further includes an exposure operation of exposing the substrate to form an exposed first region and an unexposed second region in the second film after the second film-formation operation.

### [Supplementary Note 14]

The substrate processing method of Supplementary Note 1 above further includes a developing operation of developing the substrate to selectively remove the unexposed second region from the second film after the exposure operation.

### [Supplementary Note 15]

The substrate processing method of Supplementary Note 14 above further includes a first etching operation of etching the first film using the second film as a mask after the developing operation.

### [Supplementary Note 16]

The substrate processing method of Supplementary Note 15 above further includes a second etching operation of etching the underlying film using the first film and the second film as the mask after the first etching operation.

### [Supplementary Note 17]

The substrate processing method of Supplementary Note 5 above further includes an exposure operation of exposing the substrate to form an exposed first region and an unexposed second region in the first film and the second film after the second film-formation operation.

### [Supplementary Note 18]

The substrate processing method of Supplementary Note 17 above further includes a developing operation of developing the substrate to selectively remove the unexposed second region from the first film and the second film after the exposure operation.

### [Supplementary Note 19]

The substrate processing method of Supplementary Note 18 above further includes an etching operation of etching the underlying film using the first film and the second film as a mask after the developing operation.

### [Supplementary Note 20]

A substrate processing method includes:
preparing a substrate including an underlying film, a first film on the underlying film, and a second film on the first film, wherein the first film has a higher secondary electron emission coefficient than the underlying film, the second film is a metal-containing resist film, and each of the first film and the second film has an exposed first region and an unexposed second region; and
developing the substrate to selectively remove the unexposed second region from the first film and the second film.

### [Supplementary Note 21

A substrate processing system includes:
one or more substrate processing apparatuses; and
a controller configured to control the one or more substrate processing apparatuses to execute:
preparing a substrate including an underlying film;
forming a first film on the underlying film, the first film being made of a material containing an element having a higher EUV absorption cross section than the underlying film; and
forming a second film on the first film, the second film being a metal-containing resist film.

### [Supplementary Note 22]

A device manufacturing method includes:
preparing a substrate having an underlying film;
forming a first film on the underlying film, the first film being made of a material containing an element having a higher EUV absorption cross section than the underlying film; and
forming a second film on the first film, the second film being a metal-containing resist film.

### [Supplementary Note 23]

A non-transitory computer-readable recording medium storing a program that causes a computer of a substrate processing system,
wherein the substrate processing system includes:
one or more substrate processing apparatuses; and
a controller configured to control the one or more substrate processing apparatuses to execute:
preparing a substrate including an underlying film;
forming a first film on the underlying film, the first film being made of a material containing an element having a higher EUV absorption cross section than the underlying film; and
forming a second film on the first film, the second film being a metal-containing resist film.

According to one exemplary embodiment of the present disclosure, it is possible to provide a technique for adjusting the exposure sensitivity of a resist film.

The above embodiments are described for the purpose of explanation and are not intended to limit the scope of the present disclosure. Each embodiment may be modified in various ways without departing from the scope and spirit of the present disclosure. For example, some constituent elements in one embodiment may be added to another embodiment. In addition, some constituent elements in one embodiment may be replaced with corresponding constituent elements in another embodiment.

What is claimed is:

1. A substrate processing method, comprising:
a preparation operation of preparing a substrate having an underlying film;
a first film-formation operation of forming a first film on the underlying film, the first film being made of a material containing an element having a higher EUV absorption cross section than the underlying film; and
a second film-formation operation of forming a second film on the first film, the second film being a metal-containing resist film.

2. The substrate processing method of claim 1, wherein the first film contains at least one metal selected from a group consisting of Sn, At, Bi, Ti, Pb, Xe, I, Te, Sb, Hg, Au, Cd, In, Ge, and Ag.

3. The substrate processing method of claim 1, wherein the first film contains Sn.

4. The substrate processing method of claim 2, wherein a composition ratio of the metal in the first film is higher than a composition ratio of a metal in the second film.

5. The substrate processing method of claim 1, wherein the first film is a metal-containing resist film.

6. The substrate processing method of claim 1, wherein in the first film-formation operation, the first film is formed using a dry process.

7. The substrate processing method of claim 1, wherein in the first film-formation operation, the first film is formed using a wet process.

8. The substrate processing method of claim 1, wherein the second film contains at least one metal selected from a group consisting of Sn, Hf, and Ti.

9. The substrate processing method of claim 1, wherein the second film contains Sn.

10. The substrate processing method of claim 1, wherein the second film is thicker than the first film.

11. The substrate processing method of claim 1, wherein in the second film-formation operation, the second film is formed using a dry process.

12. The substrate processing method of claim 1, wherein in the second film-formation operation, the second film is formed using a wet process.

13. The substrate processing method of claim 1, further comprising: after the second film-formation operation, an exposure operation of exposing the substrate to form an exposed first region and an unexposed second region in the second film.

14. The substrate processing method of claim 13, further comprising: after the exposure operation, a developing operation of developing the substrate to selectively remove the unexposed second region from the second film.

15. The substrate processing method of claim 14, further comprising: after the developing operation, a first etching operation of etching the first film using the second film as a mask.

16. The substrate processing method of claim 15, further comprising: after the first etching operation, a second etching operation of etching the underlying film using the first film and the second film as the mask.

17. The substrate processing method of claim 5, further comprising: after the second film-formation operation, an exposure operation of exposing the substrate to form an exposed first region and an unexposed second region in the first film and the second film.

18. The substrate processing method of claim 17, further comprising: after the exposure operation, a developing operation of developing the substrate to selectively remove the unexposed second region from the first film and the second film.

19. The substrate processing method of claim 18, further comprising: after the developing operation, an etching operation of etching the underlying film using the first film and the second film as a mask.

20. A substrate processing method, comprising:
preparing a substrate including an underlying film, a first film on the underlying film, and a second film on the first film, wherein the first film has a higher secondary electron emission coefficient than the underlying film, the second film is a metal-containing resist film, and each of the first film and the second film has an exposed first region and an unexposed second region; and
developing the substrate to selectively remove the unexposed second region from the first film and the second film.

21. A substrate processing system, comprising:
one or more substrate processing apparatuses; and
a controller configured to control the one or more substrate processing apparatuses to execute:
preparing a substrate including an underlying film;
forming a first film on the underlying film, the first film being made of a material containing an element having a higher EUV absorption cross section than the underlying film; and
forming a second film on the first film, the second film being a metal-containing resist film.
